(19) United States
(12) Patent Application Publication
(10) Pub. No.: US 2019/0347746 A1
(43) Pub. Date: Nov. 14, 2019

(54) BUILDING CONSTRUCTION TRACKING DEVICE AND METHODS

(71) Applicant: Innovative Construction Technology Enterprises, Inc., Phoenix, AZ (US)

(72) Inventors: Timothy H. Duncan, Scottsdale, AZ (US); David C. Francis, Mission Viejo, CA (US)

(73) Assignee: Innovative Construction Technology Enterprises, Inc., Phoenix, AZ (US)

(21) Appl. No.: 16/410,150

(22) Filed: May 13, 2019

Related U.S. Application Data
(60) Provisional application No. 62/670,137, filed on May 11, 2018.

(51) Int. Cl. G06Q 50/08; G06Q 10/06; G06F 3/0481; G06T 19/00

(52) U.S. Cl. CPC G06Q 50/08; G06Q 10/063118; G06F 17/5004; G06F 3/04815; G06T 19/006; G06Q 10/067

(57) ABSTRACT

A device executes an application that uses an augmented reality experience on a building construction site to provide productivity tracking for projects. The tracking compares the field installation against a coordinated construction model to provide real-time feedback on the completion of the project. Markers are used to determine a location of the device so that the appropriate model data is made available. The data is assimilated into key performance indicators and reports for project stakeholders.

### FIELD OF THE INVENTION

The present invention relates a device and associated methods for receiving models and information regarding a construction project and then tracking completion of the project.

### DESCRIPTION OF THE RELATED ART

Management of building construction projects involves knowing what has been installed or erected on the construction project site and what remains to be installed or erected. This knowledge is critical for managing the construction project to assure it is completed on time and within budget. Accurate tracking of construction performance allows project managers to monitor labor performance, bill or invoice as key milestones are met, and provide historical data to better bid on future work.

Such tracking may involve a manual process lacking consistency and a reasonable degree of accuracy. Examples of manual processes include a project team member walking around the construction project site with a set of blueprints and marking what has been installed on paper drawings. The marked up drawings are manually measured and the information is transcribed to a spreadsheet when done. The process is repeated throughout the project at scheduled times, typically weekly. Other techniques may include on-site inspections or a “best-guess” based on physical observations and the foreman's previous work experience. These processes slow, subjective and inaccurate.

### SUMMARY OF THE INVENTION

The disclosed embodiments provide an automated solution that can execute on devices, such as laptops, smartphone, tablets, mobile devices, and the like. These devices are already being used on the construction site. The disclosed embodiments may provide an increased level of accuracy, progress reporting for specific construction teams, or building systems. This feature allows contractors to better manage resources to deliver their construction projects on time and within budget. Further, because the data is digital and shared easily, the disclosed processes facilitate historical data reporting that benefits contractors to submit better bids on future work.

The disclosed embodiments pertain to using three-dimensional (3D) computer aided drafting (CAD) models with an option of interactive augmented reality or “Free-Flight” 3D mode experience through which the user tracks the construction progress of designated building systems throughout the construction of the project. Key performance dashboards and reports are generated for stake holders, thereby allowing them to better manage the project budget and completion dates.

The disclosed embodiments introduce the concept of placing markers into the models that allow a user to orient the systems and projects at the location of the project site. As the user moves around the construction site, the view on the disclosed tracker device is updated to show systems and their status. The user also may update the status without having to return back to a computer terminal or update the model away from the construction site. Updates to elements within the system may occur in real-time so that other users may be informed of the completion status of a project.

A method for tracking completion of a construction project at a project site is disclosed. The method includes combining a project model for the construction project with at least one augmented reality marker. The method also includes downloading the combined project model to a tracker device over a network. The method also includes synchronizing the combined project model with a physical location at the project site using the at least one augmented reality marker. The method also includes displaying the combined project model on the tracker device. The project model corresponds to the construction project. The method also includes selecting a system from the construction project within the combined project model. The method also includes updating a status for an element within the system using the combined project model.

A method for tracking a status of a system of a construction project. The method includes opening a project model using an application on a tracker device. The tracker device is a mobile device connected to a network. The method also includes selecting a system having a plurality of elements within the project model. The method also includes synchronizing the project model using an augmented reality marker within the project model with a physical marker at a location. The method also includes displaying a three-dimensional representation of the system on the tracker device with reference to the location. The method also includes selecting a status for at least one element of the plurality of elements using the three-dimensional representation of the system.

A construction project tracking system also is disclosed. The system includes a server to store a three-dimensional project model. The system also includes a tracker device having a display, a memory, and a processor to execute instructions stored in the memory. The instructions include an application to execute on the tracker device. The application is configured to receive the project model from the server. The application also is configured to retrieve the project model downloaded to the memory. The application also is configured to display the project model on the display. The application also is configured to interact with the project model. The system also includes a physical marker including a graphical code. The graphical code to uniquely identify the physical marker. The application is configured to synchronize the project model with a location of the physical marker such that the project model is displayed with reference to the location.

### BRIEF DESCRIPTION OF THE DRAWINGS

Various other features and attendant advantages of the present invention will be more fully appreciated as the same becomes better understood when considered in conjunction with the accompanying drawings.

FIG. 1A illustrates a block diagram of a tracker device to implement processes for building installation tracking according to the disclosed embodiments.

FIG. 1B illustrates an application architecture for use within the tracker device according to the disclosed embodiments.

FIG. 2A illustrates a block diagram of the tracker device within a network according to the disclosed embodiments.

FIG. 2B illustrates a tracker device at a construction project site including markers according to the disclosed embodiments.

FIG. 3A illustrates a block diagram of components used to generate a 3D CAD model for use with the tracker application according to the disclosed embodiments.

FIG. 3B illustrates a marker according to the disclosed embodiments.

FIG. 3C illustrates a marker according to the disclosed embodiments.

FIG. 3D illustrates an AR marker layout sheet showing placed markers at a construction project site location according to the disclosed embodiments.

FIG. 4A illustrates a flowchart for tracking a building construction project according to the disclosed embodiments.

FIG. 4B further illustrates the flowchart for tracking a building construction project according to the disclosed embodiments.

FIG. 5 illustrates a flowchart for generating a 3D CAD model for use on a construction project site location according to the disclosed embodiments.

FIG. 6 illustrates a flowchart for synchronizing a 3D CAD model with location markers according to the disclosed embodiments.

FIG. 7 illustrates a flowchart for using a 3D CAD model at a construction project site according to the disclosed embodiments.

FIG. 8 illustrates a flowchart for updating and completing use of the application according to the disclosed embodiments.

FIG. 9 illustrates a screen of the application in use on a tracker device according to the disclosed embodiments.

FIG. 10 illustrates a screen of the application in use on a tracker device according to the disclosed embodiments.

FIG. 11 illustrates a screen of the application in use on a tracker device according to the disclosed embodiments.

FIG. 12 illustrates a screen of the application in use on a tracker device according to the disclosed embodiments.

FIG. 13 illustrates a screen of the application in use on a tracker device according to the disclosed embodiments.

FIG. 14 illustrates a screen of the application in use on a tracker device according to the disclosed embodiments.

### DETAILED DESCRIPTION OF THE PREFERRED EMBODIMENTS

Reference will now be made in detail to specific embodiments of the present invention. Examples of these embodiments are illustrated in the accompanying drawings. While the embodiments will be described in conjunction with the drawings, it will be understood that the following description is not intended to limit the present invention to any one embodiment. On the contrary, the following description is intended to cover alternatives, modifications, and equivalents as may be included within the spirit and scope of the appended claims. Numerous specific details are set forth in order to provide a thorough understanding of the present invention.

The disclosed embodiments use a mobile handheld field device, such as a laptop, smartphone, tablet, and the like, to receive input in real-time from the field. Preferably, the disclosed embodiments are used in conjunction with a building construction project. In such a project, there are many different components and systems that must be built or accounted for. The disclosed embodiments utilize a project engineering design model or a coordinated construction shop model in a 3D model environment for tracking. The disclosed tracker device is connected to a system to provide real-time feedback in the form of a cloud-based report from the field for immediate data feedback.

The disclosed embodiments may provide real-time information on the amount of material to be installed, the percentage complete during installation, and the productivity of the installation crew. The information provided may be immediately fed back to the project manager and the estimating team for status on installation status and productivity rates because the system is cloud-based. The disclosed embodiments automate tracking field productivity and status utilizing the same model for design of fabrication but provide immediate cloud-based information.

Other features include tying in the disclosed processes into Autodesk BIM 360 or another project management software, for model and other potential data references. Ease of use is also a factor for the non-technical end user. In other words, a person may walk around the construction project site and use the handheld device to accomplish installation tracking and feedback. Any sized contractors may access the application to utilize the disclosed embodiments. The application may be subscription-based to keep costs low and varied with the workload. The disclosed embodiments may be implemented on existing devices and platforms to lower hardware implementation costs.

In some embodiments, a user logs into the application to initiate a session. A screen is displayed on the device with statistics from a previously opened project, if applicable. If there are no pending projects, then the device displays a warning screen that guides the user to the add project screen. A coordinated construction model is uploaded or accessed on the add project screen. Supported file types for the model may include .DWG, RVT, DGN, .IFC, .NWD, .NWC, and the like.

At any point, the user can change projects via the project menu. From the project detail menu, the user is presented with an overall summary of each floor in the project and the option to see more details on the state of any systems on the floor via the level display. The device then may display the status of a specific system via the system detail display. If the system does not exist, the device of the disclosed embodiments may establish it along with the install start date via the new system menu. At various touch points, the device can enter the user into the augmented reality data capture screen. In addition, the user can request project performance reports, reset password(s), and support.

Once the user enters the augmented reality interface, the display of the disclosed device shows a merged view of what physically has been constructed and the various systems that will be constructed. The to-be-built systems are pulled from the coordinated construction model, as disclosed above. The application executing on the device may synchronize the physical location of the user on the construction site to accurately align the model via visual targets having readable codes, such as a QR code, placed on the construction site with corresponding location markers embedded in the coordinated construction model.

As the user moves around the site, the display changes according to the location in reference to the project and systems. The device displays what is uploaded from the model hosting site. The interface include at least six (6) drop-down menus, such as (a) the building system being tracked, (b) the current level or floor, (c) a back button to return to the previous screen, (d) a sync button to establish a link between the model and the physical location on the construction site, (e) a feedback display area, and (f) a set status button to set the status of the selected objects.

The workflow of construction project site tracking is disclosed in a greater detail below. An overview, however, may be presented here for illustrative purposes. The user filters or isolates the model by level and system for viewing clarity by selecting the desired system. The user proceeds to select the appropriate objects from the augmented reality window that represents what is being tracked. The user highlights what has been constructed as he or she performs an inventory of the construction project site. The highlight may be accomplished multiple ways by touching each component, doing a linear drag across the components, or doing a window box to select multiple components on the screen to indicate being an active selection. Once the user adds all the elements to the current selection, the user changes the status using a menu option and the disclosed embodiments save the selection group to add the level, system, date, and status of the selected elements to a data set. The application uses the data sets to formulate key performance reports for project stake holders.

The reports are purposed in a tabular or dashboard format that provides insight into a percentage of completion to date based on total linear footage or pieces of a system or systems versus the installation tracking criteria based on the dataset. Filters will be available to track performance for a given-time period, utilizing percentage of completion and installation performance based on defined system tracking criteria. The performance results can be used as historical data for bidding future work, evaluation criteria for sub-contractor performance and re-hires, and the like.

Thus, the disclosed tracker device provides construction project site productivity tracking and reporting. It uses both augmented reality or free flight viewing options to interact with a 3D CAD model to select and set installation statuses. The disclosed embodiments enable real-time monitoring of construction site progress that provides accurate installation status information for project scheduling, billing, and installation productivity data for project estimation. Features of the disclosed embodiments include ease of use and minimal to no hardware costs, such as special devices or computers. The disclosed tracker device also provides real-time reports and uses existing data and collaboration sites.

One of the viewing modes for use of the tracker device is augmented reality. The disclosed embodiments display the constructability model in the built environment. The model may be displayed on specific location of the construction project site. The user will synchronize the model to a marker placed in the field that corresponds to a defined point in the model.

The other option is “Free Flight” viewing mode, which refers to use of a virtual 3D CAD model “only” view or interaction outside of the augmented reality mode. The user may zoom out to view the overall model. The user also may zoom in utilizing a window view. The overall model view is not related to a specific reference point on the project.

It may serve as an alternate option to data collection that allows for quicker collection due to a larger viewing area. The user can set installation status via free flight mode without being on the construction project site.

In either viewing mode, a user can select objects and set a status for each object. An example of statuses may be not installed, need rework, tested, inspected, insulated, balanced, commissioned, user defined status, and the like. The user may select the objects on the construction site by swiping, such as dragging a pointer or finger along a path to select touched objects. The user also may select objects by picking and choosing a single object. The user also may select objects by forming a box, or selecting a corner on the screen then tracing other corners to form the box. Every object within the box is selected. Within either viewing mode, an object may be selected to display the object's properties.

The disclosed embodiments also may implement a dashboard within the tracker device. The dashboard displays the selected system. It also allows for the entry of a cost code and displays it after entry. Budget hours also may be entered and displayed. The dashboard also displays the total hours logged in a log hours screen. The disclosed embodiments may calculate a budget percentage completion based on total hours logged divided by budget hours.

Other features of the disclosed embodiments include displaying the selected level of the construction project site along with the total linear footage in the selected system, the linear footage status set as rework, and the linear footage status set as installed. The disclosed embodiment also may calculate an installed percentage completion based on liner feet installed divided by total footage of the system.

The disclosed dashboard also may provide a log hours button that allows a user to enter hours spent, crew size (number of workers), and date, such as the date that the hours were worked. One also may view hours report to display a log of all hours, crew size, and dates. Other features include external reporting that presents all model data and status data that allows a user to generate multiple metric options. The tracker device and associated application also may synchronize data back to the model for a visual status update. It also may provide the option to report in either English/Imperial or metric units.

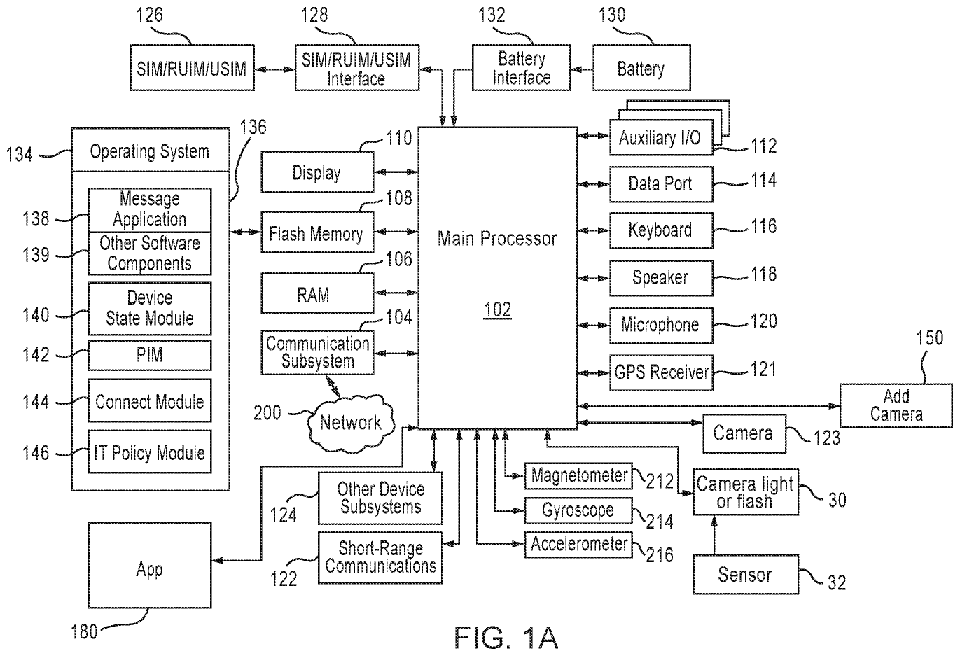

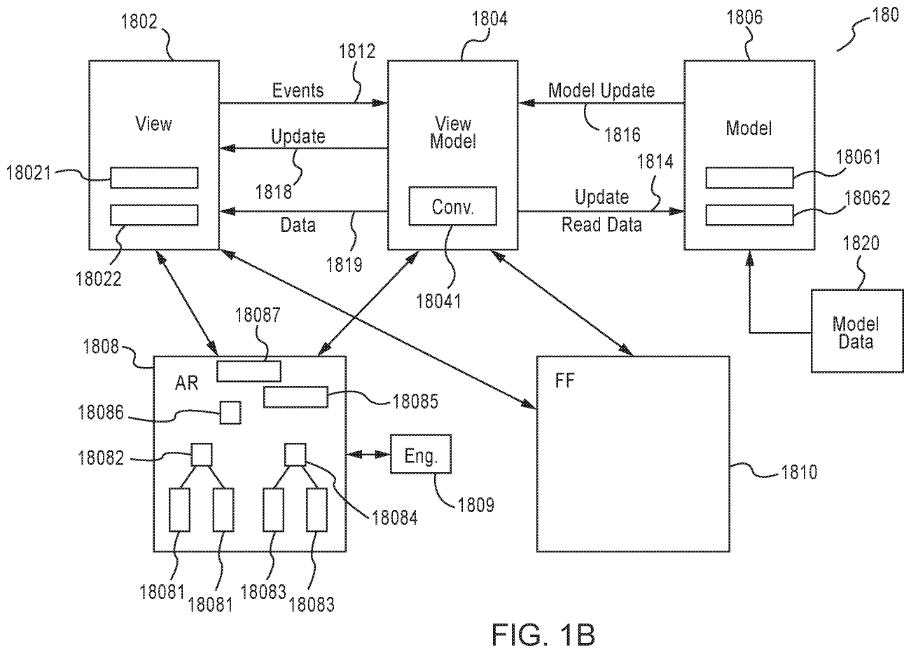

FIG. 1A depicts a block diagram of a tracker device 100 to implement processes for implementing building construction project tracking according to the disclosed embodiments. Device 100 may be a laptop, smart phone, tablet, and the like. In some embodiments, device 100 may be referred to as a mobile device. The components shown provide the platform to execute applications that track completion of a construction project. The processes and functionality used to accomplish this is disclosed in greater detail below. Tracker device 100 may include additional components that are not shown.

Device 100 includes a main processor 102 that controls the overall operation of the components within the device. Communication functions, such as voice and data communications, are performed through a communication subsystem 104. Communication subsystem 104 receives and transmits messages over network 200. In some embodiments, communication subsystem 104 is configured in accordance with the Global System for Mobile communication (GSM) and General Packet Radio Services (GPRS) standards, which are used worldwide. Other communication configurations may be applicable such as the 3G, 4G and 5G networks, such as EDGE, UMTS, and HSDPA, LTE, Wi-max, and the like. Further, new standards may be defined that will have similarities to the network behavior disclosed below. The wireless link connecting communication subsystem 104 with network 200 represents one or more different Radio Frequency (RF) channels, operating according to defined protocols specified for GSM/GPRS communications.

Main processor 102 may control additional subsystems, such as a random access memory (RAM) 106, a flash memory 108, a display 110, an auxiliary input/output (I/O) subsystem 112, a data port 114, a keyboard 116, a speaker 118, a microphone 120, a global positioning system (GPS) receiver 121, short range communications subsystem 122, a camera 123, a camera light or flash 30, and other device subsystems 124. Device 100 also may include an additional camera 190. For example, camera 123 may be located on the rear or back side of device 100 while camera 190 is on the front side.

Main processor 102 also may interact with sensors within device 100. For example, a magnetometer 212 may act like a miniature Hall-effect sensor that detects the Earth's magnetic field along three perpendicular axes, X, Y, and Z. Magnetometer 212 produces a voltage that is proportional to the strength and polarity of the magnetic field along the axis each sensor is directed. The sensed voltage indicates the magnetic field intensity. Thus, magnetometer 212 can detect the relative orientation of mobile device 100 relative to the magnetic “North” of the Earth.

Device 100 includes a gyroscope 214. Gyroscope 214 may be a sensor that measures the rotational velocity along the roll, pitch, and yaw axes of mobile device 100. Gyroscope 214 may utilize micro-electromechanical system (MEMS) technology to determine these values. As device 100 is rotated through use, gyroscope 214 can determine these values to provide to applications executing on device 100.

Another sensor for device 100 may be an accelerometer 216 to determine acceleration along a given axis. As device 100 moves along a certain direction, accelerometer 216 measures movement and acceleration as well as initial position and speed. Accelerometer 216 also may measure the tilt of device 100. Accelerometer 216 also may implement MEMS technology.

Some of the subsystems of device 100 perform communication-related functions.

Other subsystems may provide “resident” or on-device functions. For example, display 110 and keyboard 116 may be used for communication-related functions, such as entering a text message for transmission over network 200, and device-resident functions such as a calculator or task list.

Device 100 also may send and receive communication signals over network 200 after required network registration or activation procedures have been completed. Network access is associated with a subscriber or user of device 100. To identify a subscriber, device 100 may use a subscriber module component, or “smart card,” 126, such as a subscriber identify module (SIM), a removable user identity module (RUIM), or a universal subscriber identify module (USIM). For example, SIM/RUIM/USIM component 126 is inserted into an interface 128 in order to communicate with network 200. Once component 126 is inserted into interface 128, it is coupled to main processor 102.

Device 100 may be a battery-powered device that includes a battery interface 132 to receive at least one battery 130. Battery 130 may be a smart battery with an embedded microprocessor. Battery interface 132 is coupled to a regulator that assists battery 130 in providing power V+ to device 100. Alternatively, device 100 may utilize other power supply sources, such as micro fuel cells, instead of battery 130.

Operating system 134 and software components 136 execute on device 100 with main processor 102. Software components 136 are disclosed in greater detail below. Operating system 134 and software components 136 are executed by main processor 102 and are stored in a persistent storage such as flash memory 108, which may alternatively be a read-only memory (ROM) or a similar storage element. Operating system 134 may be temporarily loaded into a volatile storage, such as RAM 106.

Operating system 134 manages the components of device 100 and provides common services for applications running on the mobile platform. It also may act as an intermediary between software components 136 and the hardware components on device 100. For example, operating system 134 may manage input and output memory allocation.

A subset of software components 136 that control basic device operations, including data and voice communication applications, may be installed on device 100. Software components 136 may include a message application 138, a device state module 140, a personal information manager (PIM) 142, a connect module 144, and an IT policy module 146. These applications are disclosed in greater detail below. When launched, the different applications are executed by main processor 102. In some embodiments, an application converts device 100 and main processor 102 into a special purpose machine that is configured to perform a specific function using the components of the mobile device, such as building construction project tracking.

Message application 138 allows a user of device 100 to send and receive electronic messages. The messages may be stored in flash memory 108. Device state module 140 provides persistence to ensure that important device data is stored in persistent memory, such as flash memory 108, so that the data is not lost when device 100 is turned off or loses power. PIM 142 includes functionality for organizing and managing data items of interest to the user. Such items may include email, contacts, calendar events, voice mails, recent phone calls, and the like. PIM 142 interacts with network 200 via communication subsystem 104. Connect module 144 implements the communication protocols that are required for device 100 to communicate over wireless infrastructure and any host system, such as an enterprise system, which is authorized to interface with the mobile device. IT policy module 146 receives IT policy data that encodes the IT policy and may be responsible for organizing and securing rules specified in an IT policy.

Other types of software applications or components 139 may be installed on device 100. Software applications 139 may be pre-installed applications, other than message application 138, or third party applications, which are added after the manufacture of device 100. Examples of third party applications may include games, calculators, social media applications, utilities, and the like. Software applications 139 may be loaded onto device 100 through at least one of network 200, auxiliary I/O subsystem 112, data port 114, short-range communications subsystem 122, or any other suitable device system 124.

Data port 114 may be any suitable port that enables data communication between device 100 and another computing device. Data port 114 may be a serial or a parallel port. In some embodiments, data port 114 may be a USB port that includes data lines for data transfer and a supply line that can provide a charging current to charge battery 130 of device 100.

For voice communications, received signals are output to speaker 118 and signals for transmission are generated by microphone 120. Although voice or audio signal output is accomplished primarily through speaker 118, display 110 may be used to provide additional information, such as the identity of a calling party, duration of a voice call, or other voice-call related information.

Construction project tracking, or tracker, application 180 also is stored and executed on device 100. Construction project tracking application 180 may be stored in RAM 106 or flash memory 108. When launched, main processor 102 executes instructions provided by tracker application 180 to provide the functions and processes disclosed below. Further, tracker application 180, using main processor 102, converts device 100 into a project tracking and information device. Device 100, using components shown in FIG. 1A, receives data and information to track the progress of a construction project. Tracker application 180 then instructs device 100 to communicate this condition over network 200, or to the user of the device.

The processes for tracking the progress of a construction building project are disclosed in greater detail below. In summary, tracker application 180 instructs, using main processor 102, display 110 to provide screens and interfaces to capture data pertaining to the construction project. The user will use device 100 during walk throughs or inspections of the construction site. Construction project tracking application 180 also may provide interactive augmented reality or free flight mode embodiments that further enhance the tracking process.

FIG. 1B depicts an architecture for tracker application 180 for use within tracker device 100 according to the disclosed embodiments. Tracker application 180 may include the following components within the architecture: view layer 1802, viewmodel layer 1804, model layer 1806, augment reality component 1808, and free flight component 1810. These components are disclosed in greater detail below. When application 180 is executing on tracker device 100, these components of the architecture are implemented. Processor 102 and other components disclosed in FIG. 1A are configured to support the disclosed components and their functionalities.

View layer 1802, viewmodel layer 1804, and model layer 1806 provide a clear separation of concerns between various components of application 180. The layers communicate and exchange data with each other yet keeps data within each layer separate from the other layers. All the layers may interact with augmented reality component 1808 and free flight component 1810, though FIG. 1B shows data exchange with viewmodel layer 1804.

View layer 1802 includes components pertaining to the visuals provided on device 100. These components are what users see and with which they interact. The components may capture input from the user on device 100. View layer 1802 includes user input (UI) component 18021 and UI component 18022. UI components 18021 and 18022 may provide the interface to select objects from the 3D CAD model displayed on device 100 using the swiping, single object selection, box, or lasso methods disclosed above. A UI component also may allow the user to input data or queries. The UI components capture user input events 1812 that are sent to viewmodel layer 1804.

Model layer 1806 includes components pertaining to data for the models used within application 180. Model layer 1806 may receive model data 1820, as disclosed in greater detail below. Model data 1820 preferably is the 3D CAD model data used in the application to track completion of the construction project. Model data 1820 may be input into model layer 1806 when a marker is detected or a location indicated to tracker device 100. Using network 200, tracker device 100 obtains model data 1820. Data components 18061 and 18062 may represent the data for the 3D CAD model. Additional components may be stored in model layer 1806. As shown in FIG. 1B, model layer 1806 provides model updates 1816 to viewmodel layer 1804 as well as receives updates or read data requests 1814 from the viewmodel layer.

Viewmodel layer 1804 includes components that interface between view layer 1802 and model layer 1806. Viewmodel layer 1804 converts raw data from model layer 1806 to information that is presentable to the user through view layer 1802. This layer provides a degree of separation between the data for the 3D CAD models and the information presented to the user on tracker device 100. Converter component 18041 of viewmodel layer 1804 may convert the raw data into viewmodel data 1819 that is used by view layer 1802 to generate the visual display of the job to the user.

Augmented reality component 1808 interacts with view layer 1802 and viewmodel layer 1804 to provide the object and associated data to be used by application 180 to generate the displayed model in the built environment. In other words, the disclosed embodiments show the 3D CAD model in its actual environment on tracker device 100. To do so, application 180 needs data and objects to synchronize or correlate to the data from the 3D CAD model. Augmented reality component 1808 may use engine 1809 to generate the data to provide to view layer 1802 or viewmodel layer 1804 to generate the displayed model for the construction project.

Items within augmented reality component 1808 may be created using engine 1809. The logic may be divided into specific classes, known as monobehaviours, that are attached to a controller game object within a single scene for the 3D CAD Model. The classes handle functionalities such as transform tools, selection tools, cache management, and the like. Referring to FIG. 1B, classes 18081 are attached to controller game object 18082. Classes 18083 are attached to controller game object 18084. A forge loader object 18085 is in charge of the model replication process performed within augmented reality component 1808. All of the classes may be tied to a central controller class 18086 that is in charge of handling the augmented reality view's runtime. A bridge class 18087 may be defined as a communications layer between operating system 134 shown in FIG. 1A and view layer 1802. Other tools may be used for text renderers, model serialization/deserialization, and simple animations.

Free flight component 1810 also may interact with view layer 1802 and viewmodel layer 1804. As disclosed above, free flight component 1810 may enable a free flight mode that allows display of the 3D CAD Model, without the use of a marker. Free flight component 1810 may utilize the same structure as augmented reality component 1808.

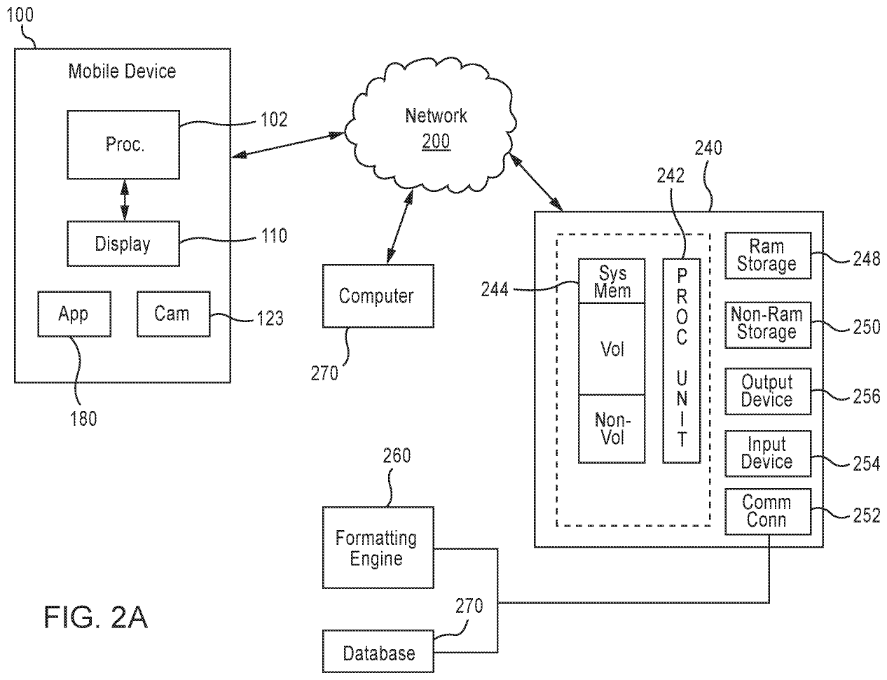

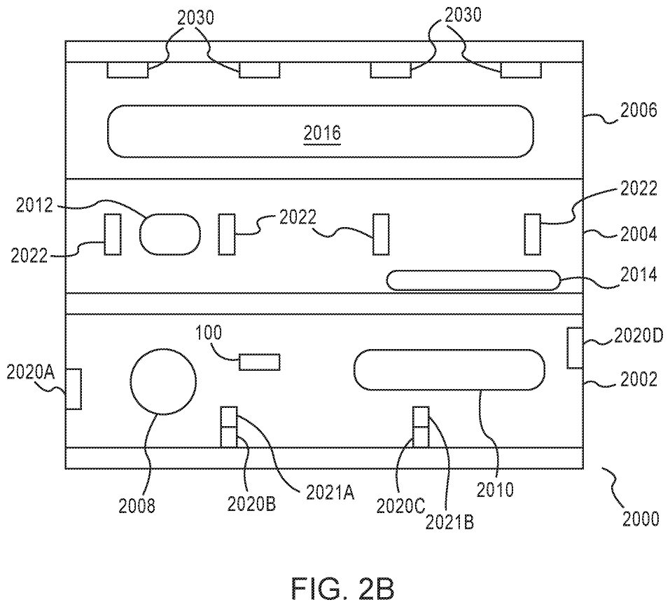

FIG. 2A depicts a block diagram of tracker device 100 within network 200 according to the disclosed embodiments. Tracker device 100 is shown with some of the components disclosed above, such as main processor 102, display 110, and camera 123. The other components are not shown for brevity. Device 100 is connected to network 200. Network 200 is connected to other devices. Server 240 is shown as being connected to network 200 and may transmit and receive data from device 100. Server 240 may be a computing device running a process to serve web pages, data, and the like.

Device 100 and server 240 may be identified within network 200 using a uniform resource locator (URL) or internet protocol (IP) address. Server 240 may communicate documents, web pages, data, and the like to device 100. A browser application of other software components 139 may receive a web page from server 240. This information may be formatted in the HTML or XHTML format, and may provide navigation to other web pages via hypertext links. Web pages may be requested and served from server 240 using hyper-text transfer protocol (HTTP) or wireless application protocol (WAP).

Static web pages may be defined from files of static text stored within the file system of server 240. Server 240 may construct the XHTML or HTML for each web page when it is requested by a browser to generate dynamic web pages. Formatting engine 260 may dynamically or statically create or retrieve the web pages in response to requests for documents received by server 240. A database 270 may store information about client devices, such as device 100, store web pages to be server by server 240. While formatting engine 260 and database 270 are shown as being separate devices. These components, however, may be included as part of server 140 or run on the same device.

Server 240 may be understood to be an exemplary general-purpose computing device having at least one processing unit 242 and memory 244. Depending on the exact configuration and type of computing platform, memory 244 may be volatile, such as random access memory (RAM), non-volatile, such as read-only memory (ROM), flash memory, and the like. Server 240 also may include additional features and functionality. In some embodiments, server 240 may include additional storage, such as magnetic or optical disks or tape. This storage may be removable or non-removable. Such additional storage may be shown in FIG. 2 as removable storage 248 and non-removable storage 250. Server 240 also includes a variety of computer-readable media. Computer-readable media may be any available media that can be accessed by server 240. This media includes volatile and non-volatile media as well as removable and non-removable media.

Memory 244, removable storage 248, and non-removable storage 250 are all examples of computer storage media. Computer storage media include RAM, ROM, electrically erasable program read-only memory (EEPROM), flash memory, or other memory technology. It also may include CD-ROM, digital versatile disks (DVD), or other optical storage, magnetic cassettes, magnetic tape, magnetic disk storage, or other magnetic storage devices.

Server 240 may contain communications connection 252 that allows the server to communicate with other devices. For example, these devices may not have access to network 200. Server 240 also includes input devices 254, such as a keyboard, mouse, pen, stylus, voice input device, touch input device, and the like. Output devices 256 may include a display, speakers, printers, and the like.

In some embodiments, device 100 may instruct server 240 to perform operations and provide data in order to execute processes to promote tracking of a building construction project. As device 100 collects and displays information and data, the information and data may be stored at server 240 for later retrieval by the application. A user may access computer 270 connected to network 200 for accessing the stored information on server 240. These components may all work together to support the disclosed processes as they execute on device 100.

Construction project tracking application 180 also may take advantage of server 240. As disclosed above, construction project tracking application 180 converts tracker device 100 into an building construction project tracking device when executed on main processor 102. Tracker application 180 brings in data pertaining to the construction project to present to the user. The user then inputs data into device 100 to track the progress of the project. The data collected by application 180 may be sent to server 240, as well as other devices connected to network 200. Server 240 may further process the data using processing unit 214 or store the data in memory 244 for later retrieval. Tracker application 180 also may send the transformed data to server 240 as well.

If the user uses construction project tracking application 180 on a regular basis, then it would connect to server 240 for updates and information not yet received at device 100. Server 240 also may store a history of collected data to reduce the space needed in memory by construction project tracking application 180. A foreman using construction project tracking application 180 may access stored files for specific dates or historical data as the project progresses to completion.

In some embodiments, server 240 may provide model data 1820 to tracker device 100. This data is stored in model layer 1806 until used to displaying the appropriate model to the user. Server 240 also may execute an application like application 180 that configures the server to become a tracker server. In other words, server 240 performs the functions disclosed below to enable construction project tracking according to the disclosed embodiments.

FIG. 2B depicts tracker device 100 at a construction project location 2000 including markers according to the disclosed embodiments. The construction project location 2000 may resemble a building having multiple levels with different construction projects, or systems on each level. For example, each level may be a floor in the building. The construction project location 2000 includes lower level 2002, middle level 2004, and upper level 2006. Upper level 2006 may be considered an attic or utility level in that people do not normally enter this level.

Each level has its own projects. For example, lower level 2002 may include projects 2008 and 2010. These projects may be set as objects within a 3D CAD model of the construction project location 2000. Alternatively, the objects may be further defined in the projects. For example, project 2008 may be an entry way lobby project having a specific configuration of the walls or other structures. Objects within project 2008 may include a partition to the rear of level 2002 along with sunken floor for chairs and tables. Project 2010 may refer to the electrical subsystem for use on level 2002. Objects in project 2010 may include wiring, outlets, junction boxes, and the like. Electrical subsystem projects may be included on every level of construction project location 2000.

Middle level 2004 includes project 2014. Project 2014 may refer to flooring or carpeting for the level. The user may want to track completion of such projects. Upper level 2006 may include project 2016, which refers to the HVAC subsystem to provide air and heat in construction project location 2000. All projects may connect to other projects but are treated as separate groupings in the construction tracking system. The projects defined in construction project location 2000 will be displayed on tracker device 100 when using tracker application 180.

Construction project location 2000 also includes location markers that help designate how to display the projects on tracker device 100 and provide location information for the user as he/she moves around construction project location 2000. Each level includes its own location markers. Location markers may be placed on a wall, floor, ceiling, or structure within construction project location 2000. In some embodiments, the location markers may be known as field reference devices. Location markers also include designators, which are components that identify each marker as distinct from other markers. For example, location markers may use visual graphical codes, such as a QR code, that is scanned by tracker device 100 to designate its location within the construction project location.

Upper level 2002 includes location markers 2020A-D. Location marker 2020A may be placed in a wall near the entry of the level. Location marker 2020B may be placed on the floor. Location marker 2020C also may be placed on the floor at a distance from location marker 2020B. Location marker 2020D may be placed on a wall in the rear of level 2002. A stairway to level 2004 may be near location marker 2020D.

The location markers on level 2002 include designators to distinctly identify each marker and its location. For example, location marker 2020B includes designator 2021A. As tracker device 100 approaches location marker 2020B, it receives input, such as a signal or scanned code, based on designator 2021A. As can be seen in FIG. 2B, tracker device 100 is nearer to location marker 2020B than location marker 2020A or 2020C. As the user moves toward location marker 2020C, tracker device 100 will receive input of designator 2021B to adjust the construction model shown in the device. Thus, the user will be shown real-time information of projects within construction project location 2000. For example, project 2010 may be displayed when tracker device 100 is in the vicinity of location marker 2020C.

Middle level 2004 includes location markers 2022. These location markers are shown placed on a wall. Location markers 2022 also include designators that distinguish them from each other but also from location markers in different levels. Upper level 2006 includes location markers 2030. Location markers 2030 may be installed on the ceiling in that they are out of the way from someone moving within level 2006. As disclosed, multiple location marker 2030 may be located near project 2016. As one moves along the location of project 2016, the location markers update the model data shown to the user.

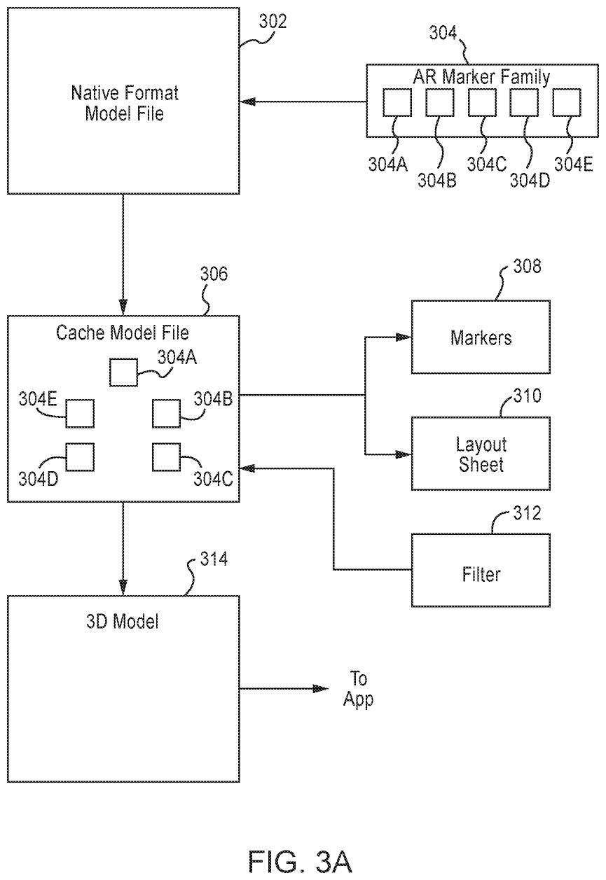

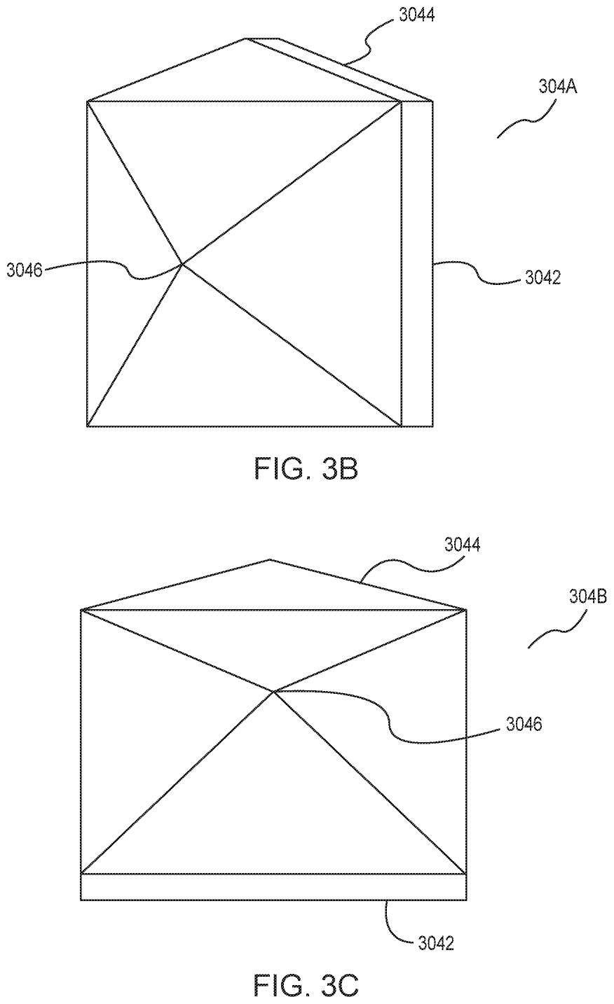

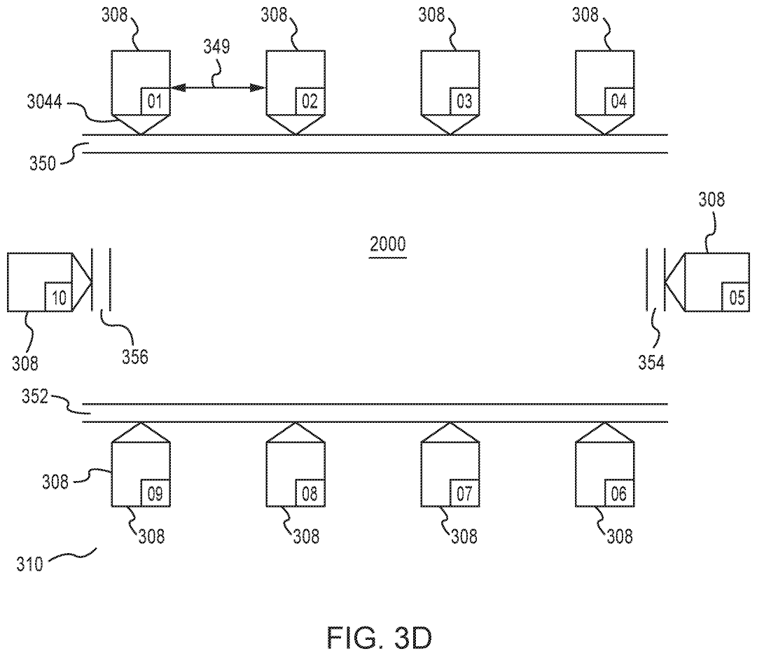

FIG. 3A depicts a block diagram of components used to generate a 3D CAD model file 314 for use with tracker application 180 according to the disclosed embodiments. A few items are desired before beginning the generation of 3D CAD model file 314. One should have device 100, application 180, a platform, such as server 240 or 270 to receive completed 3D CAD model files, the native CAD software for file generation, and the original project trade model(s) and reference models in their native platforms, preferably filtered to just the trade elements by level. These will be needed in which to place AR reference markers and to generate the appropriate file to upload to the user account.

Before a model can be loaded into tracker application 180, augmented reality markers are loaded into the native format model file 302 as reference points that the field will use to synchronize the model to the field environment. FIG. 2B shows the physical markers at construction project site 2000. These may be the physical markers placed as reference points to use with the 3D CAD model in application 180. FIG. 3A depicts the markers placed within a native format model file 302 for construction project site 2000. One selects the project that tracker application 180 will use and the location of the native format model files. The issue for construction or release for fabrication version of the native model files should be used for tracking. In some embodiments, these files may be located at server 240 or 270.

A user identifies the layout strategy for locating the physical markers based on the project layout. Preferably, markers are located at each outside column outside of normal core construction traffic or the best available spots on the projects for access. Markers should be located about 20 to about 35 feet apart to re-synchronize the augmented reality model used in application 180 as one walks the project site. Structural columns may provide good field reference locations for markers. Markers can be located horizontally on the floor or vertically on a wall or column, as shown in FIG. 2B. The more reference points, the better to re-synchronize the model as needed while in use.

FIG. 3A shows augmented reality (AR) marker family 304 of a plurality of AR markers. AR markers may refer to markers located in the model. AR marker family 304 populates native format model file 302 by being inserted in to the model at the designated, or agreed upon, locations. Accuracy of the layout of AR markers 304 is important, as each one of these locations correspond to a reference point in the field that a physical marker will be placed to orientate the 3D model to the environment of construction project site 2000. One should not modify or scale AR marker family 304 as the markers provided also are important to the augmented reality component 1808 to identify the location (X, Y, Z coordinates) in the model in relation to the field as well as set the scale of the augmented reality.

AR marker family 304 includes AR markers 304A, 304B, 304C, 304D, and 304E. Additional AR markers may be used as needed within native format model file 302. AR markers may be named based on a numeric identifier for each AR marker required for native format model file 302. Each marker may include at least three elements. Each marker must have a unique number as two markers with the same number identifier cannot be used by tracker application 180. Other elements of the AR markers are disclosed by FIGS. 3B and 3C.

FIG. 3B depicts a vertical or wall mount marker 304A according to the disclosed embodiments. Any AR marker in marker family 304 may be a vertical marker, but marker 304A is used for illustrative purposes. As noted, a vertical marker is placed in the vertical plane, such as a wall or column at the project site. FIG. 3C depicts horizontal or floor mount marker 304B according to the disclosed embodiments. Any AR marker in marker family 304 may be a vertical marker, but marker 304B is used for illustrative purposes. As noted, a horizontal marker is placed in the horizontal plane, such as a floor or ceiling at the project site.

Each marker in marker family 304 may be represented as follows, as shown in FIGS. 3B and 3C. “XX” as used below may refer to the number identifier (01, 02, 03, and so on) used for each marker. This feature is disclosed in greater by FIG. 3D. AR marker XX 3042 refers to a square element that is used to locate the X,Y center point of the AR marker. It also sets the 1:1 scale of the augmented reality to the actual printed marker when located in the field. AR marker XX 3042 may refer to the same condition in markers 304A and 304B. In other words, the location of the center point and the scale applies to vertical and horizontal markers.

AR marker XX up 3044 refers to a triangular element that locates the X, Y, Z point in the AR marker. This element may differ between vertical markers and horizontal markers. AR marker XX up 3044 locates the positive Z direction towards the ceiling or sky when mounted as vertical marker 304A. AR marker XX up 3044 locates the X or Y direction facing away from the user when mounted in the horizontal or floor/ceiling position, as shown by marker 304B.

AR marker XX forward 3046 refers to a pyramid element of the AR marker that locates the X, Y, Z point at the X or Y direction for vertical marker 304A. The point of the pyramid element faces towards the user when mounted in the vertical plane. AR marker XX forward 3046 refers to the pyramid element of the AR marker that locates the X, Y, Z point at the positive Z direction for horizontal marker 304B. The point of the pyramid element faces towards the ceiling or sky when mounted in the horizontal plane.

Upon completion of locating markers 304A-E in model file 302, cache model file 306 is generated. As shown in FIG. 3A, markers 304A, 304B, 304C, 304D, and 304E are located in different places in the model. Physical markers 308 also are generated along with AR marker layout sheet 310. Physical markers 308 are shown as markers 2020A-D, 2022, and 2030 in FIG. 2B. Physical markers 308 will be used at the term to refer to these items within the disclosed system for simplicity. In addition to the layout of markers 308 at construction project site 2000, AR marker layout sheet 310 includes dimensions or elevation reference annotations for each AR marker location. Sheet 310 will be used for location and orientation of the AR markers for field placement used in conjunction with tracker application 180.

FIG. 3D depicts an AR marker layout sheet 310 showing placed physical markers 308 at a construction project site location 2000 according to the disclosed embodiments. Before tracker application 180 can be used in the field, physical markers 308 are placed at their appropriate locations at construction project site 2000. Layout sheet 310 may refer to site 2000. Markers 308 are shown with their number identifiers 01, 02, 03, and so on. It should be noted that markers 308 in FIG. 3D are not the same number as AR markers 304A-E. If so, then only five markers 308 would be placed.

Physical markers 308 also include the triangular element of AR marker XX up 3044. This is placed according to the rules outlined above for vertical or horizontal placement of the markers. In placing markers 308, one references AR marker layout sheet 310 with dimensions or elevations reference annotations for each AR marker location. For example, markers 308 may be separated by a distance 349. Offset distances 350, 352, 354, and 356 may refer to the distance from markers 308 from a reference point, such as the floor, wall, ceiling, and the like. For example, offset distances 350 and 352 may be 2 feet from the floor if markers 01-04 and 06-09 of markers 308 are vertical markers while offset distances 354 and 356 may be 1 foot from the wall if markers 05 and 10 are horizontal markers. The markers will be oriented as disclosed above, depending on which plane they are placed.

Referring back to FIG. 3A, filter 312 may be applied to cache model file 306. Depending on model usage by tracker application 180, some elements should be filtered out to maximize efficiency of the tracker application productivity. For example, each model may be isolated by floor, such as levels 2002, 2004, and 2006 in FIG. 2B, for viewing in application 180. Certain elements on a level might have multiple level attributes based on location between floors, or levels, as in risers, or different level annotation based on user error.

Depending on the tracking strategy, multiple models may be filtered and generated based on usage, phasing, or cost code breakouts of an installation. Potential strategies may include rough-in install elements only, mains versus branches, finish install elements only, equipment or fixtures only, insulation or wrap only, two models representing conduit and cable tray and the same model for pulled wire or cable completion, or sleeves or penetrations. The following elements should be filtered or frozen before export to generate 3D CAD model 314: all insulation or wrap elements, any unnecessary or non-trackable accessories, such as gauges, thermometers, inserts, and the like, all welds, gaskets, bolt sets, and joint elements, and all annotation should be filtered from the model.

Thus, 3D CAD model 314 is generated to use with tracker application 180 in an augmented reality environment upon completion of the installation tracking and model generation strategy. 3D CAD model 314 may be stored at a cloud-based server for use in the field. Use of the model at construction project site 2000 is disclosed in greater detail below.

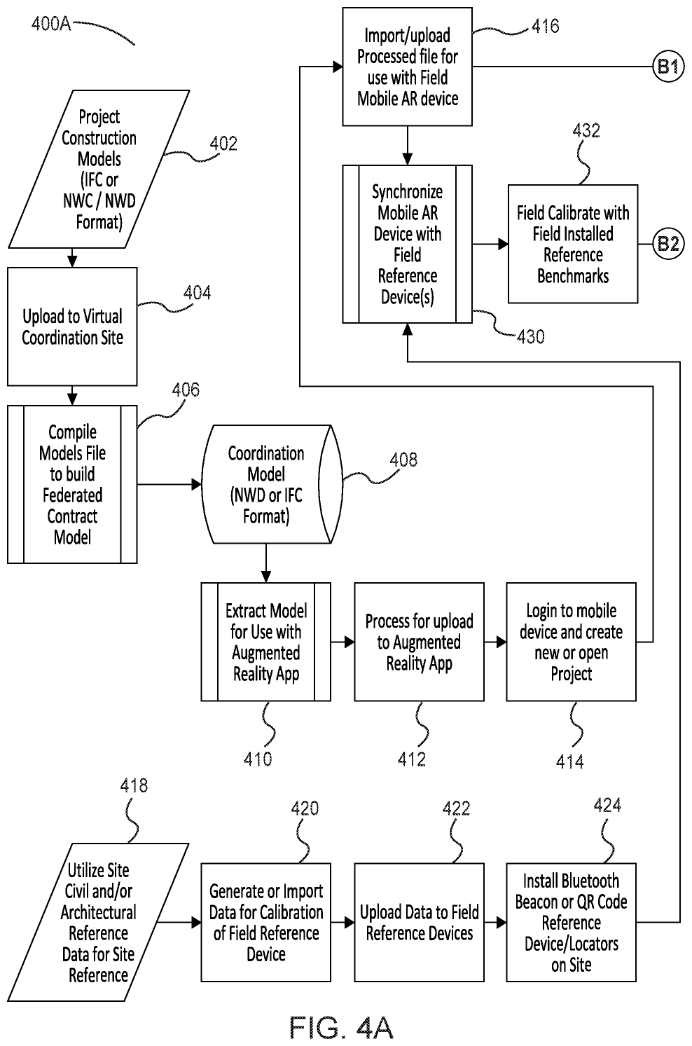

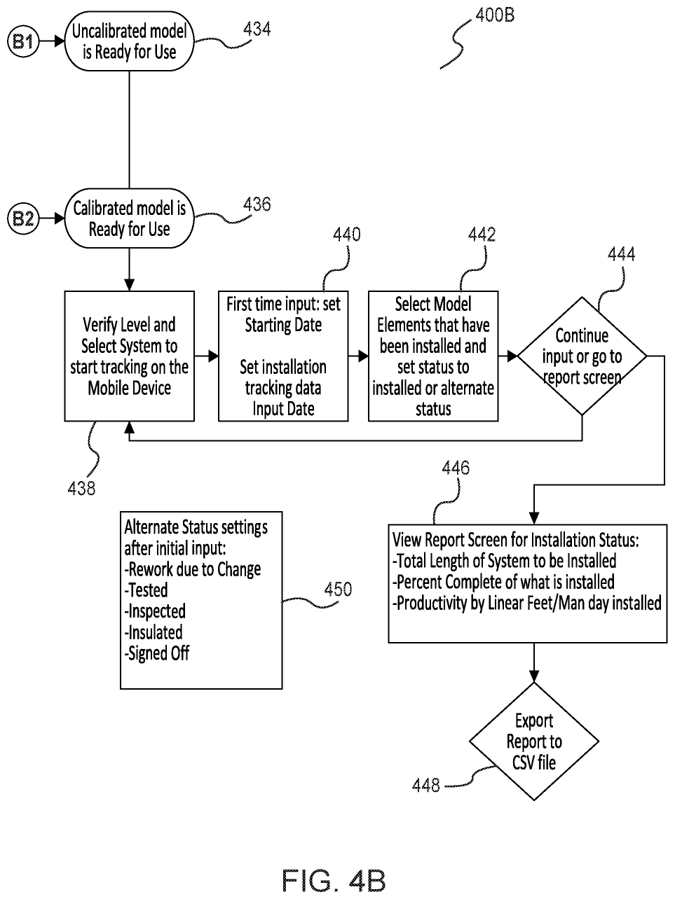

FIGS. 4A and 4B depict a flowchart 400 for tracking a building construction project using tracker application 180 on device 100 according to the disclosed embodiments. The processes disclosed by flowchart 400 may be implemented by the features disclosed in FIGS. 1A-B and 2A-B. Where appropriate, the discussion of FIGS. 4A-B will refer back to the components shown in FIGS. 1A-B, 2A-B, and 3A-D for illustrative purposes.

Step 402 executes by providing project construction models for the disclosed process. The construction model files that may be utilize Navisworks NWD format or Industry Foundation Class (IFC) format, both industry standards. The files may be generated from a software program as Navisworks has the ability to convert and read over a variety of different computer-aided design (CAD) formats. IFC is an international standard format for three-dimensional (3D) CAD file exporting. Both data types provide the model element data associated with the system or item being installed. The disclosed embodiments utilize the project model developed during the design phase or the construction phase as the baseline for data capture. The construction phase model may be preferred as it may yield a higher level of accuracy. The file for the project model is used for reference and may be modified to include color changes to model elements for improved status recognition. The model also may be used in its basic form to walk around the field and identify installed elements or utilize field reference points, or location markers, in the form of QR codes or visual markers to synchronize the building with the model for easier reference to the location. Model elements data is used to identify the level, system, lengths, and, in some cases, material and size if needed to generate status and productivity. These features are disclosed in greater detail below.

Step 404 executes by uploading the project construction models to the virtual coordination site. Step 406 executes by compiling the models to build a Federated Contract Model (FCM). Step 408 executes by providing a coordination model in the NWC or IFC format. Step 410 executes by extracting the coordination model for use with the augmented reality component, such as component 1808 executed on device 100 disclosed above. Application 180 converts device 100 into a special purpose machine to execute the disclosed embodiments. The application provides the ability to open the file and allow the user to filter what system is being tracked. The models may be by level, which simplifies the loading to the device. A naming format may be used to identify that the correct model is being used. A process assigns a building level to the model element that makes identifying the level associated with the element simpler.

Step 412 executes by processing the coordination model for upload to the augmented reality application. Some of the data points may be adjusted for use in the application. Step 414 executes by the user logging onto the mobile device, such as device 100, and creating a new project or launching an open project. This step is disclosed in greater detail below. Step 416 executes by importing or uploading the processed model file from step 412 for use with the field mobile augmented reality device. Flowchart 400 proceeds to step B1.

Steps 402-416 relate to obtaining and processing the appropriate model for use in the field device. Steps 418-424 relate to gathering the data needed for the construction project site and reference operations. Step 418 executes by utilizing site civil or architectural reference data for site reference. This data may be retrieved from a database or input into the application on the device. Step 420 executes by generating or importing data for calibration of the field reference device. This data may be stored at a server accessible by device 100, such as database 270. The data may be correlated with the construction project site.

Step 422 uploading the reference data to the field references devices, or location markers. Referring back to FIG. 1A, the reference data may be made available over network 200 to device 100 for use by application 180. Step 424 executes by installing the visual markers or QR code reference device or locators on site, also known as designators used on the location markers disclosed in FIG. 2B.

Step 430 executes by synchronizing the mobile augmented reality device with the field reference device. In some embodiments, there may be more than one field reference device. In this step, the disclosed process uses visual markers or QR codes to synchronize the mobile device, or device 100, location to reference points within the building structure. The data for the reference points may be compiled and provided in step 430. This feature may simplify the tracking process of the model within the building structure.

Step 432 executes by field calibrating with field installed reference benchmarks. The calibration phase locates the model reference points with the field reference points. The reference point may be in the form of a model element that is unique and easily identifiable in the model. The reference point is either identified by the surveyor and provided by the general contractor or it is generated by the installing contractor. Either way, these reference points need to be inserted into the model at the defined locations and given a unique reference to be identified in the field when calibrating the model in the field. Flowchart 400 proceeds to step B2.

Step 434 executes by providing an uncalibrated model that is ready for use. The uncalibrated model may not be synchronized and calibrated with visual markers or codes that related to the reference points used in the model. Such a model may not make sure of the location markers and information during the tracking process. Step 436 executes by providing the calibrated model from step 432 that is ready for use in the application.

Step 438 executes by verifying the appropriate level and selecting a system to start tracking using the disclosed device. The user may verify, for example, that he or she is on the correct floor according to the display and then provides an input selecting which system to track. Step 440 executes by setting installation tracking data with the input date. For a first time input, the application may set the starting date for tracking the project.

Step 442 executes by selecting model elements that have been installed and set status for these elements to installed or alternate status. The user views the selected system on the display provided by the application in an augmented reality environment. The elements of the system are shown in the model provided on the device. The user may change the status of the elements using the displayed system on the device. Step 444 executes by determining whether to continue receiving input or go to the report screen. If step 444 is to continue input, then flowchart 400 returns to step 438.

If step 444 is to stop input, then step 446 executes by the user viewing the report screen for installation status. The information on the project is displayed on the device once all the data has been received and analyzed. Such information may include the total length of the system to be installed, the percent complete of what is installed, or the productivity by linear feet per man day of what was installed. The analytics provide real-time information to the user as well as visual confirmation.

Step 450 executes by providing alternate status settings for model elements after initial input. The status settings may include rework due to change, that the element is tested or being tested, and that it is inspected or insulated. The user also may indicate that he or she has signed off on the status of that model element. The user also may flag the element shown in the application for further action.

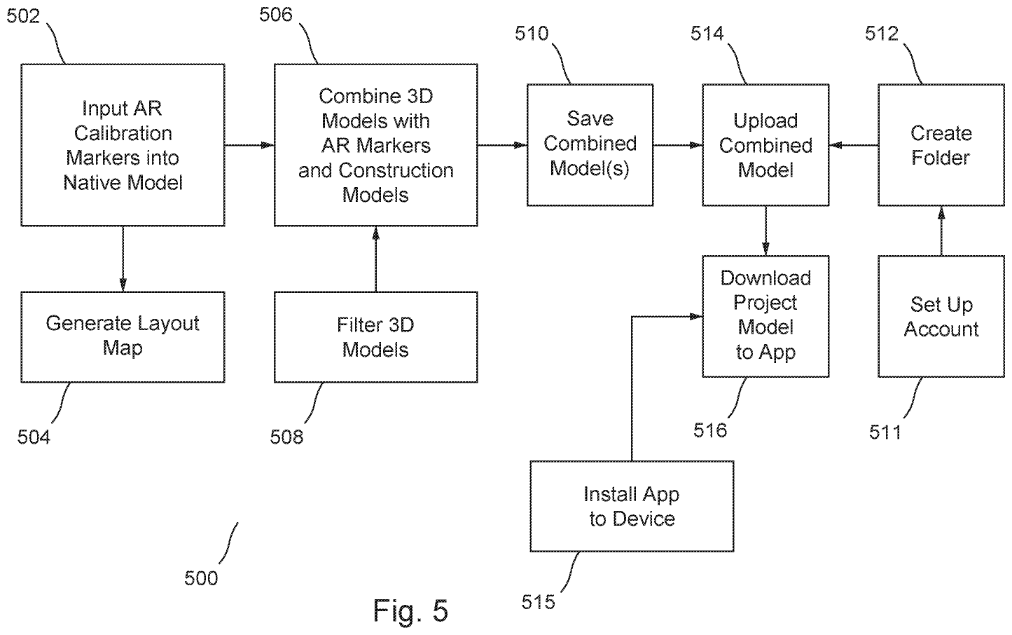

FIGS. 5-8 relate to FIG. 4 in that these figures disclose tracking a building construction project using tracker application 180 on device 100. FIGS. 5-8 disclose the processes for using the model in the field with markers and an AR environment in greater detail. As with FIG. 4, the processes disclosed by FIGS. 5-8 may be implemented by the features disclosed in FIGS. 1A-B, 2A-B, and 3A-D. Where appropriate, the discussion of FIG. 4 will refer back to the components shown in FIGS. 1A-B, 2A-B, and 3A-D for illustrative purposes.

FIG. 5 depicts a flowchart 500 for generating a 3D CAD model for use in tracker application 180 on a construction project site location according to the disclosed embodiments. Flowchart 500 relates to the placement of the AR markers into the native model file and generating the markers to place at the construction project site. Step 502 executes by inputting the AR markers, such as marker family 304, into the 3D CAD model, or native format model file, 302. The AR markers are used to synchronize the model to the physical markers placed at the site. Step 504 executes by generating layout map, or sheet, 310 showing the placement of the AR markers along with dimension or elevation references annotations.

Step 506 executes by combining 3D models with AR markers and construction models. Step 508 executes by filtering the 3D models for use based on tracking strategies, such as cost codes, systems, materials, and the like. In other words, various aspects of the model may be highlighted for tracking purposes. The user may only want to track a level or a system, such piping, at the site.

Step 510 executes by saving the combined model in the required format for use by tracker application 180. As noted above, a cache model file may not be useable in the application or on device 100. Thus, these model files need to be converted into a format acceptable by the application. Step 512 executes by creating an upload folder for the combined model. The cloud-based project account for the model also may be set up in step 511. Step 514 executes by uploading the combined model into the cloud-based storage account. For example, 3D model 314 may be uploaded to a storage account on server 240. A folder is set up to receive the model, which makes it accessible over network 200.

Step 515 executes by installing tracker application 180 onto tracker device 100. The user may set up an application account as well. After installation, step 516 executes by downloading the 3D CAD model, or the combined model, to tracker device 100 for use with tracker application 180. In some embodiments, the model may be stored on device 100 until application 180 is launched. In other words, the user can download the project model for use later. In other embodiments, tracker application 180 is launched and then the project model is retrieved from the cloud-based storage.

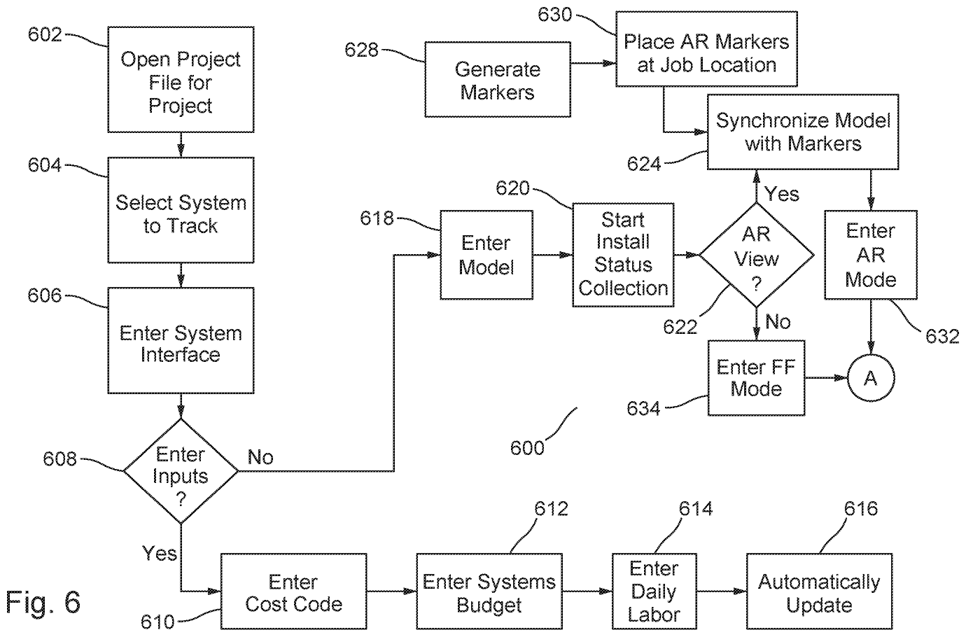

FIG. 6 depicts a flowchart 600 for synchronizing a 3D CAD model with location, or physical, markers 308 according to the disclosed embodiments. Step 602 executes by opening a project file for the construction project. Once a project file, such as file 314, is loaded in tracker application 180, each file will be shown on a projects screen. The user selects the desired project file from the listing.

Step 604 executes by selecting a system or other aspect of the project to track. When the project is loaded, a level selection screen is loaded. This screen identifies the levels available from the model upload, such as level 1, first floor, and the like. Preferably, a floor is loaded. The number of systems on each level also is identified along with the total percent completed for all systems on that level. Once a level is selected, application 180 opens a system selection screen. This screen identifies the systems available from the model upload. For example, systems may include exhaust air, supply air, outside air, and return air for level 1. The user taps on the system button text. Thus, the user may select the level and system according to step 604.

Step 606 executes by entering the system interface. The system interface may include a system status screen that identifies items from the model upload. These items include the system, level, cost code, budget hours, total hours logged, budget percentage complete, total footage of the system, linear feet of rework, linear feet installed, and installed percentage compete. These items may be displayed on tracker device 100. For example, these items may be displayed for the supply air system for Level 1 at the construction project site. Referring to FIG. 2B, level 2002 includes system 2010, which is the supply air system. The data and information for these items may be provided by the model, the user, or calculated by application 180.

Step 608 executes by determining whether the user wishes to enter any inputs or information for these items. Doing so will update the project information within application 180. If yes, then step 610 executes by entering the cost code. Step 612 executes by entering systems budget or budget hours. Step 610 or 612, or both, may be selected. These items are optional to be entered. If entered, then the budget hours are used to calculate the budget percentage complete. This data also is exported as part of the CSV report and is associated with all elements in the model for use in project management software and estimating productivity.

Another option to select for input is daily labor items. If selected, step 614 executes by entering these items. The daily labor data includes number of workers, hours, and dates. Application 180 keeps a running track of these items. Manhours per day may be entered and these show up as a calculation under total hours logged. These also are associated with the selected elements to identify labor spent on a day along with linear feet, piece or poundage of the installed elements, and the like. Thus, as tracker application 180 is used to track completion of the project, these statistics can be used to determine the productivity and costs for installing specific systems. Step 616 executes by automatically updating the items selected. Budget percentage complete automatically updates as labor hours are entered.

If step 608 is no, then flowchart 600 proceeds to step 618. Alternatively, the user may select to enter inputs then proceed to step 618 once those steps are complete. Step 618 executes by entering the 3D CAD model in tracker application 180. Preferably, the model is shown visually so that the user can view the system and level. For example, the return air system on level 1 is displayed on the screen of tracker device 100. The model is loaded into the memory of device 100, such as RAM 106 or flash memory 108.

Step 620 executes by starting install status collection in AR view or free flight mode. Step 622 executes by determining whether the user wants to enter AR view mode. If yes, then step 624 executes by synchronizing the loaded 3D CAD model with the physical markers located at the construction project site. Referring to FIG. 3D, the model synchronizes with markers 308. This step is disclosed in greater detail below. Prior to step 624, steps 628 and 630 are executed.

Step 628 executes by generating the AR physical markers. These markers should resemble those shown in FIGS. 3B and 3C. Preferably, the physical markers are generated by printing them out on paper. When printed, the scale of the marker is important to the scale of the augmented reality. Accuracy should be ensured. The markers are printed at a 1:1 scale so that edge of the border, usually shown in a black graphic, is exactly a desired size, such as 8 inches by 8 inches. Step 630 executes by placing the markers at the construction project site, preferably as outlined by layout sheet 310. Use of AR marker XX up 3044 and AR marker XX forward 3046 helps orient the physical marker properly and in correspondence with the AR marker orientation in the model.

Step 624 performs when tracker application 180 is looking for the AR marker in the field to synchronize the model to the field environment. When prompted, one should use the viewing screen in the application to hover over the appropriate AR marker in the field. When the marker is found, a found AR tracker text will display at the top of the screen. The calibrated model is now synchronized and ready to start tracking.

For example, referring to construction project site 2000, markers 308 are placed as specified on layout sheet 310. Application 180 may prompt the user to hover over marker 05 until it is captured. Preferably, marker 05 of markers 308 includes a code or other indicator recognizable by application 180 to uniquely identify that marker from the other others. Application 180 then confirms the location of the user on project site 2000 to orient the model accordingly. In other embodiments, the user may hover over any marker 308 to capture it and determine which one it is. Once application 180 recognizes the marker, it is able to determine the location and orient the model accordingly.

Step 632 executes by entering AR mode for using tracking application 180. At any time, the user may enter free flight mode, as shown in step 634. Further, if step 622 is no, then step 634 also may be executed. Free flight mode may refer to a virtual 3D model only view or interaction outside of AR mode. The user can get a global model view that is not related to a specific marker as in the augmented reality. It may allow for quicker data collection due to a larger viewing area. When the user enters free flight mode, his position in the model will be relative to his location on the construction site per the last marker location synced with. Another feature of free flight mode is that one does not need to be on the construction project site location to use it. Application 180 may provide buttons and joystick interfaces to enable free flight mode.

From either AR mode or free flight mode, flowchart 600 proceeds to A, which goes to flowchart 700 to allow application 180 to begin tracking completion of the projects for the selected system.

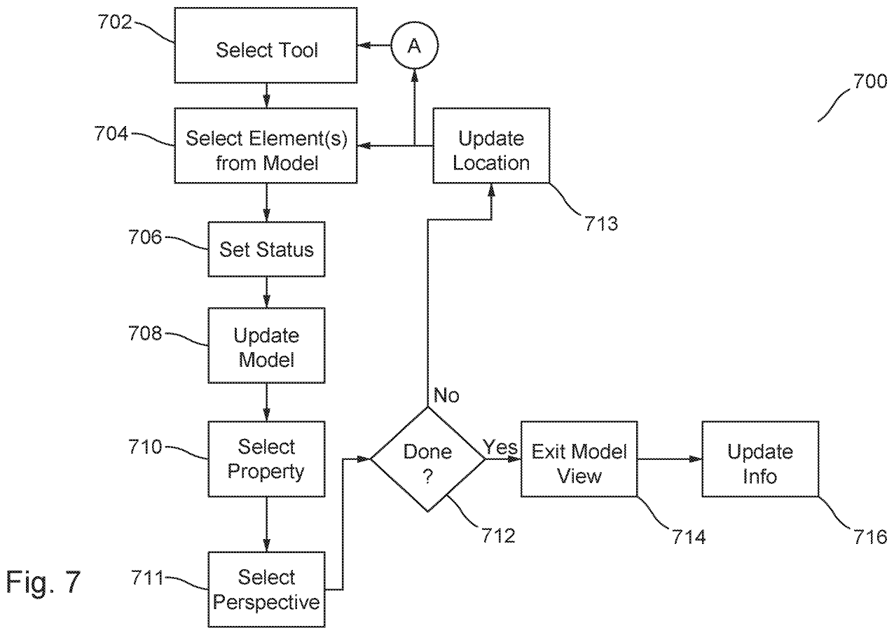

FIG. 7 depicts a flowchart 700 for using a 3D CAD model at a construction project site according to the disclosed embodiments. Flowchart 700 begins with A, which is the mode utilized by application 180. The mode may be either augmented reality mode or free flight mode. Once a mode is entered and application 180 is synced to a marker, the user may view the 3D CAD model for the construction project site to see the overlay of the CAD elements versus the installed field elements. The user may interact with application 180 and device 100 to tracking installation and progress of projects at the construction site. Flowchart 700 is disclosed below with reference to the augmented reality mode. The disclosed embodiments also may apply to free flight mode except where noted.

Step 702 executes by selecting a tool to select elements within the 3D CAD model. Tools may include single pick, linear, or lasso box. These tools are disclosed above and in greater detail below. Step 704 executes by selecting elements within the 3D CAD model. This task may be accomplished by selecting the model elements from the display screen of display 110 of tracker device 100 with a finger or pointer. The action also may be used to deselect elements as well. Elements will change color when selected and may be accounted by an “Elements Selected” count at the bottom of the display screen.

As disclosed by step 702, a tool may be chosen to select elements on display 110 in step 704. One option is the single pick selection. One selects each model element individually by picking the element with a finger or pointer. Another option is a linear selection. One selects multiple elements at a time by dragging a finger or pointer along the model elements displayed the screen to do a continuous selection. Another option is a lasso box selection. One selects the tool in step 702 using a button or other interface to change a linear option to lasso box. This tool allows the user to select multiple elements with a selection window. All items will be selected in the selection window if more than 50% of the element is within the window outline. The selection setting may be changed at any time after a selection of element or elements occurs.

Step 706 executes by setting a status for the selected elements on the screen. The selected elements may be highlighted to distinguish them from other elements of the model displayed on the screen. Once all the elements are selected individually or as a group to change their status, one may tap on the indicated button on the screen to open a selection setting options dialogue box. To change element status, one may tap on a “set to” text option in the dialogue box. By default, when the model is first opened in tracker application 180, all elements are shown as “not installed” and may be colored grey.

As status changes occur, the elements may be colored accordingly. For example, a “set to installed” status for an element may color it green. All elements in this setting will be identified as installed on the model and calculated in the installed linear feet determination in the system status interface screens. A “set to not installed” status may color an element grey. All elements in this setting will be identified as not installed on the model and will not be calculated on the installed status on the system status interface screens. A “set to needs rework” status may color an element yellow. All elements in this setting may be identified as installed items that need rework due to a design change and calculated into the linear feet rework on the system status interface screen. The colors used in the examples may be any color to distinguish the different status designations from each other. In other embodiments, a grey scale distinction may be used.

Step 708 executes by updating the 3D CAD model accordingly. Once the status is applied, the model elements will change color to signify the status of the element. Step 710 executes by selecting a property of an element to view. This step may be optional. The user may press a properties button on the screen. When an element is selected and the properties button is selected, certain quick reference data may be displayed in the lower middle of the screen. Examples of properties may be size, name, system, length, weight, and the like.

Step 711 is another optional step and executes by selecting a perspective view. This option only may be available in free flight mode. It allows one to get a perspective plan view to see the status of the model or make more selections. From this view, the user also can make selections and status changes to the model as well as selecting an element and checking its properties. In other words, steps 702-710 may be executed from the perspective view in free flight mode.

Step 712 executes by determining whether the tracking process using application 180 is complete. If no, then step 713 may execute by updating the location of tracker device 100 using a marker. The user may capture the marker as disclosed above. Flowchart 700 proceeds to step 702 or 704 to start the element selection and status change processes again. If step 712 is yes, then step 714 executes by exiting the model view and applicable mode. If in the augmented reality mode, then this mode is exited. Application 180 returns to the system screen. Step 716 executes by updating the information for the selected system. For example, linear footage and total percent complete may be updated.

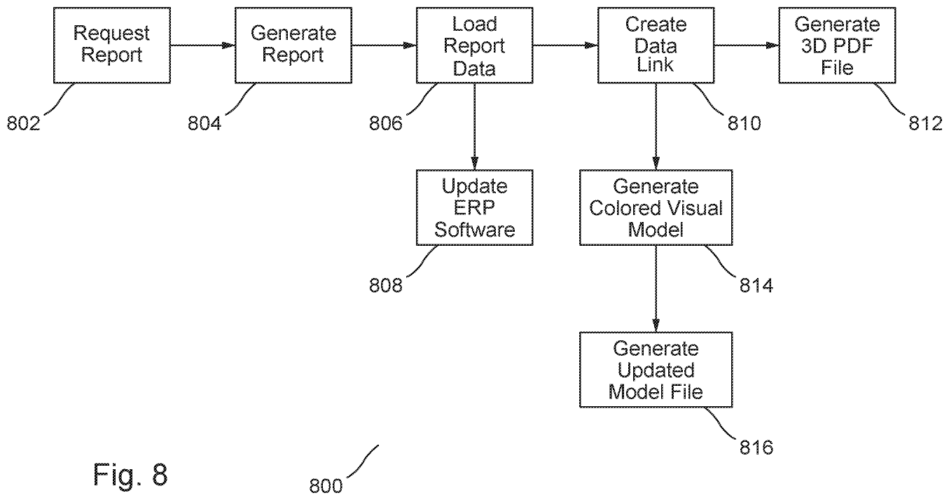

FIG. 8 depicts a flowchart 800 for updating and completing use of the application according to the disclosed embodiments. The steps of flowchart 800 may be executed after completion of flowcharts 600 and 700. Alternatively, the user may execute the steps disclosed herein at any time when using tracker application 180.

Step 802 executes by requesting a report for the selected system, project, or site. The report may be requested from the system screen. Step 804 executes by generating the report. The report is generated of all the model elements with install dates and cost codes. Step 806 executes by loading the report data. CSV file data is loaded into an import template to update project status data. Step 808 executes by updating the enterprise resource planning (ERP) software. An export template may be used to update the ERP software.

Step 810 executes by creating a data link to visual model software to generate the colored visual install status model. A couple options to present this information may be selected at this point. Step 812 executes by generating a 3D PDF file that may shared amongst other users, such as a project team. Step 814 executes by generating an updated 3D colored visual model. Step 816 executes by generating an updated model file to share electronically with other users.

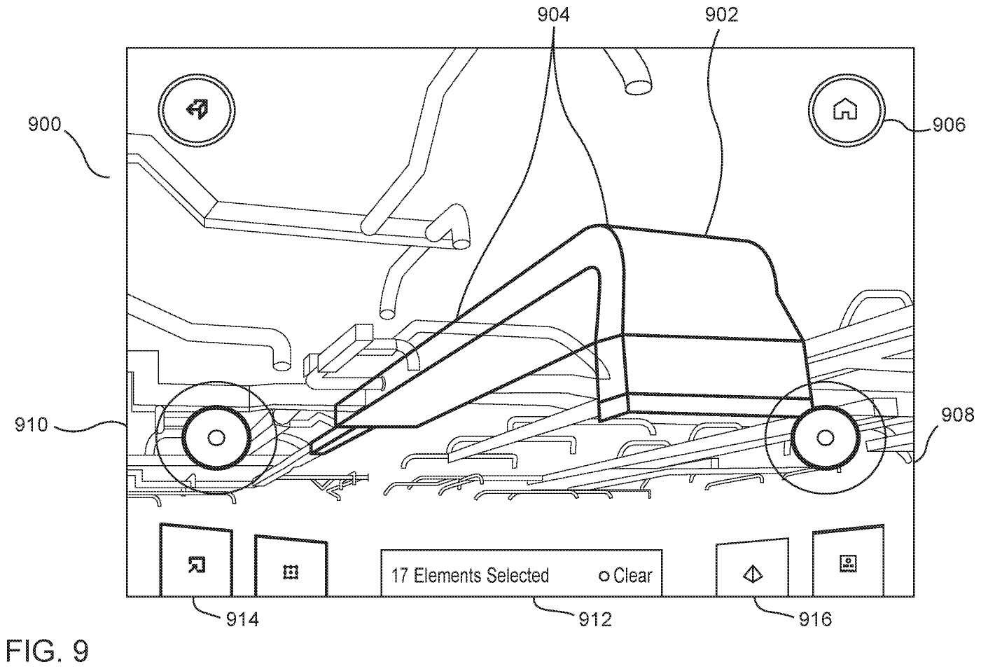

FIGS. 9-14 depicts various screens of tracker application 180 executing on tracker device 100. The embodiments disclosed by FIGS. 9-14 correspond to the processes and embodiments disclosed above. Where appropriate, reference is made to previous features disclosed above. FIG. 9 depicts a system as represented in a project model 900 with elements 902 and 904 shown within application 180 according to the disclosed embodiments. For example, project model 900 may represent return air system 910 of a construction project. The user selected system 910 from previous menu screens. An AR physical, or field reference, marker, such as a marker 308 disclosed above, is captured by tracker device 100 to synchronize project model 900 of system 910 shown in FIG. 9.

Elements 902 and 904 represent parts of system 900 are installed. The user applies the tools disclosed above to select elements 902 and 904. Element 902 may represent a part of return air system 910 exposed into a room or out of a ceiling while elements 904 represent elements enclosed within the ceiling or structure. Thus, the disclosed embodiments can account for parts of a building system not readily visible to a user. The user can determine that elements exist within the structure and act accordingly to indicate whether the elements are installed.

If selected, the elements are highlighted on the display screen. As shown, elements 902 and 904 are highlighted in contrast to the rest of return air system 910. The other elements of system 910 are not highlighted. Alternatively, the non-selected elements of system 910 may be a different color that elements 902 and 904. If the user moves in relation to return air system 910, then the view may change. For example, if the user moves towards the rear of elements 904 and away from element 902, then those elements may be presented larger as the user moves closer to them.

Application 180 also includes features that act as interfaces between the user and the project model. As shown in FIG. 1B, view layer 1802 interacts through viewmodel layer 1804 with model layer 1806. Model layer 1806 may include the file for the project model within application 180. View layer 1802 receives inputs through features disclosed below to make changes or updates to how the project model is displayed. Viewmodel layer 1804 converts the data between the displayed information and the stored information.

Application 180 displays a home button 906. The home button may return application 180 to a home or default screen. It also may return application 180 to a project screen showing information about the overall project or system. Joysticks 908 and 910 allow the user to navigate within the view provided of system 910 without actually moving. Thus, the user may stand still and navigate within the displayed project model. Joystick 908 may move the view up and down or left and right while joystick 910 moves the view forward and backwards to zoom in or out as well as side to side. Display bar 912 indicates a status of the displayed screen. As shown, it states that 17 elements have been selected using a tool within application 180. Status select button 914 may be used to change the status of the selected items. Free flight button 916 may be used to place application 180 into free flight mode.

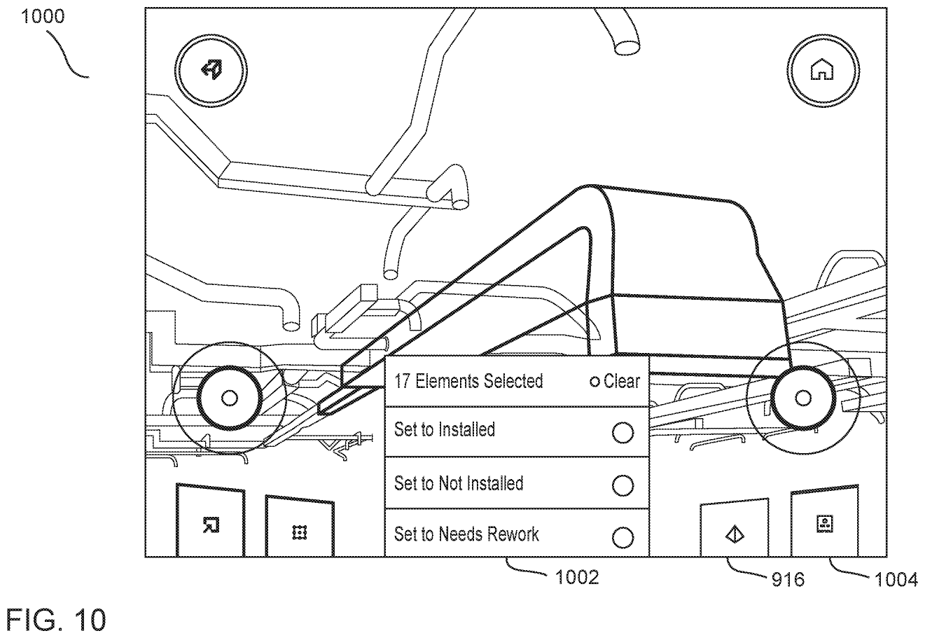

FIG. 10 depicts application 180 changing the status of elements 902 and 904 according to the disclosed embodiments. Extended display bar 1002 includes buttons for options to set the highlighted elements. As disclosed above, these options include installed, not installed, and needs rework. Once confirmed, button 1004 is used to update the information for project model 900 and return air system 910. These processes are disclosed above.

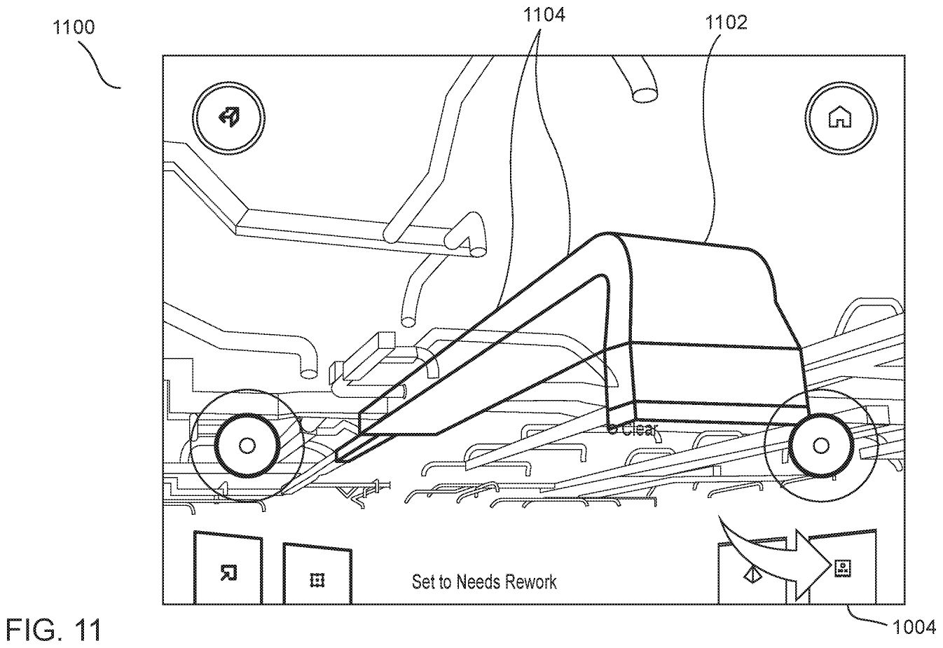

FIG. 11 depicts revised project model 900 having an updated view of system 910. Elements 1102 and 1104 correspond to elements 902 and 904, but have an updated status. In some embodiments, elements 1102 and 1104 are a different color than elements 902 and 904. View layer 1802 receives the updated data from model layer 1806 via viewmodel layer 1804. This update may be done using button 1004.

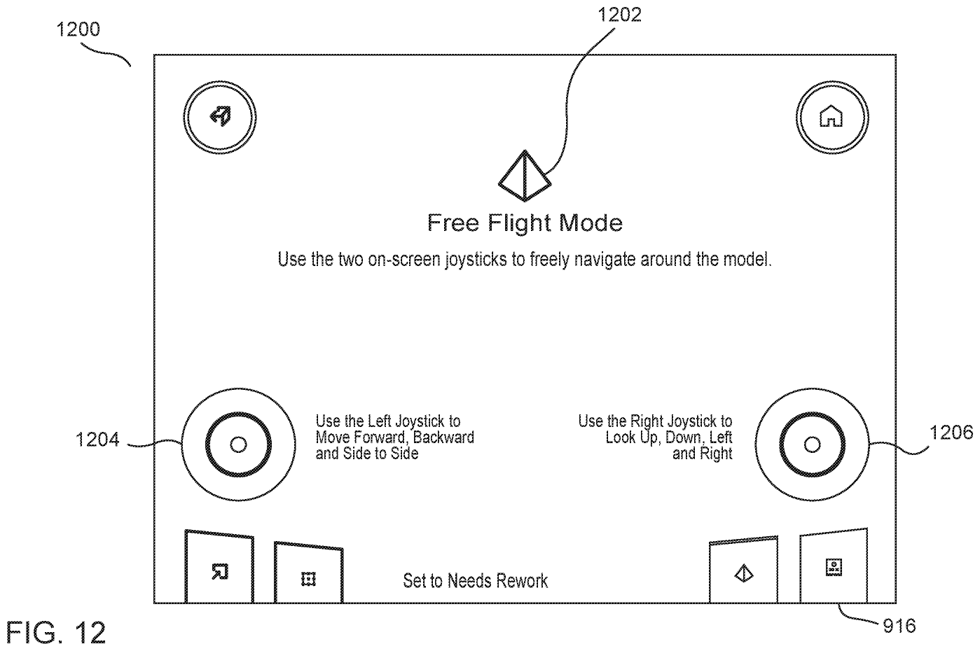

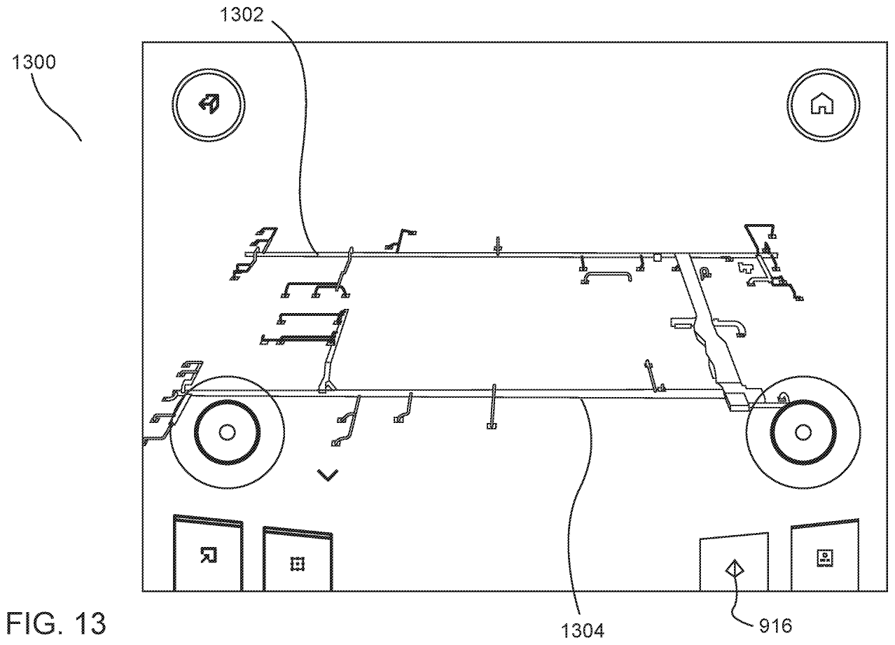

FIG. 12 depicts application 180 entering free flight mode according to the disclosed embodiments. Free flight mode, as disclosed above, may be entered instead of augmented reality mode. Augmented reality mode may be shown by FIGS. 9-11. The user selects button 916 displayed using application 180. Free flight mode allows the user to view the project model without being synchronized with a physical marker 308. Free flight mode may be suitable when the user is not at the construction site and needs to view the project model without the need to sync with a marker. Free flight mode also includes joystick 1202 and 1204 along with the other buttons used by application 180.

FIG. 13 depicts a perspective view of a system 1300 within a project model. As shown, the perspective view shows system 1300 from an upper view not really applicable to the views shown in augmented reality mode. Elements 1302 and 1304 may comprise system 1300. Elements 1302 may represent non-installed items while 1304 may represent installed items. The perspective view provides a quick high level view of the elements. The user may return to the augmented reality mode using button 916. The loaded view for free flight mode may correspond to the last physical marker 308 captured.

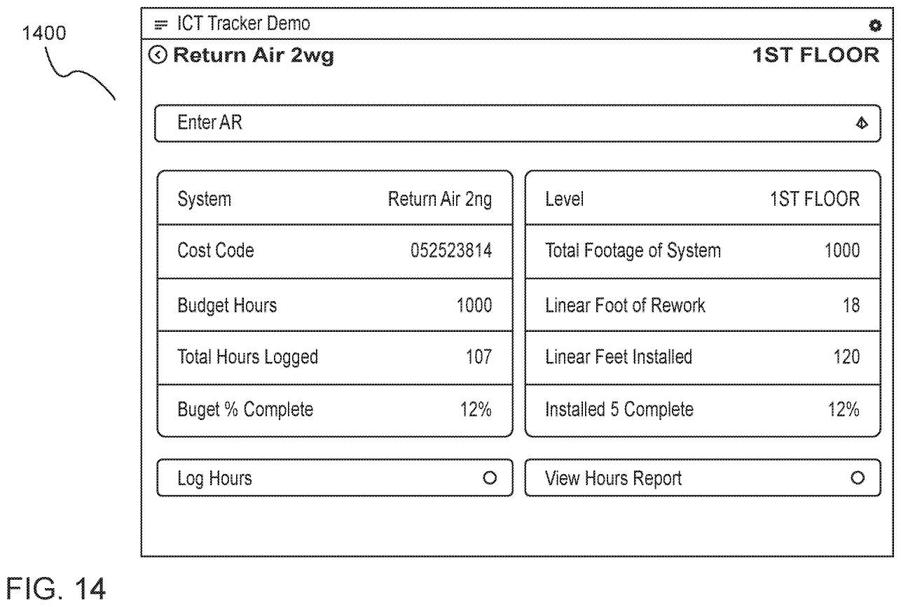

FIG. 14 depicts system summary screen 1400 according to the disclosed embodiments. As shown, screen 1400 includes information about return air system 910 that is updated after elements are selected and their statuses changed using application 180. This report also may be reproduced or forwarded as disclosed in FIGS. 4A-B and 8 above. Application 180 automatically updates any data associated with the displayed system.

It will be apparent to those skilled in the art that various modifications to the disclosed embodiments may be made without departing from the spirit or scope of the invention. Thus, it is intended that the present invention covers the modifications and variations disclosed above provided that these changes come within the scope of the claims and their equivalents.

1. A method for tracking completion of a construction project at a project site, the method comprising:
combining a project model for the construction project with at least one augmented reality marker;
downloading the combined project model to a tracker device over a network;
synchronizing the combined project model with a physical location at the project site using the at least one augmented reality marker;
displaying the combined project model on the tracker device, wherein the project model corresponds to the construction project;
selecting a system from the construction project within the combined project model; and
updating a status for an element within the system using the combined project model.

2. The method of claim 1, further comprising inputting information for the construction project onto the tracker device.

3. The method of claim 1, further comprising filtering the project model.

4. The method of claim 1, wherein the synchronizing includes synchronizing the at least one augmented reality marker with a physical marker at the project site.

5. The method of claim 4, further comprising capturing an image of the physical marker using the tracker device.

6. The method of claim 5, further comprising determining information about the physical marker from the image.

7. The method of claim 1, further comprising selecting the element using a tool to interact with the combined project model displayed on the tracker device.

8. The method of claim 1, wherein the status includes installed or not installed.

9. The method of claim 1, further comprising storing the combined project model at a server accessible over the network.

10. A method for tracking a status of a system of a construction project, the method comprising:
opening a project model using an application on a tracker device, wherein the tracker device is a mobile device connected to a network;
selecting a system having a plurality of elements within the project model;
synchronizing the project model using an augmented reality marker within the project model with a physical marker at a location
displaying a three-dimensional representation of the system on the tracker device with reference to the location; and
selecting a status for at least one element of the plurality of elements using the three-dimensional representation of the system.

11. The method of claim 10, further comprising downloading the project model from a server over the network.

12. The method of claim 10, further comprising inputting the augmented reality marker into the project model.

13. The method of claim 10, wherein the project model is a three-dimensional computer aided design (CAD) model.

14. The method of claim 10, further comprising updating a completion percentage of the system based on the status.

15. The method of claim 10, further comprising selecting the at least one element displayed on the tracker device using a tool supported by the application.

16. A construction project tracking system comprising:
a server to store a three-dimensional project model;
a tracker device having a display, a memory, and a processor to execute instructions stored in the memory;
the instructions comprising an application to execute on the tracker device, the application configured to
receive the project model from the server,
retrieve the project model downloaded to the memory,
display the project model on the display,
interact with the project model; and
a physical marker including a graphical code, the graphical code to uniquely identify the physical marker,
the application to synchronize the project model with a location of the physical marker such that the project model is displayed with reference to the location.

17. The construction project tracking system of claim 16, wherein the tracker device comprises a camera to capture an image of the physical marker at the location.

18. The construction project tracking system of claim 16, wherein the application displays the project model in an augmented reality mode.

19. The construction project tracking system of claim 16, further comprising an augmented reality marker placed in the project model, wherein the augmented reality marker is used to synchronize the project model with the physical marker.

20. The construction project tracking system of claim 19, wherein the augmented reality marker corresponds to the physical marker.
